(19) United States
(12) Patent Application Publication
(10) Pub. No.: US 2014/0261686 A1
(43) Pub. Date: Sep. 18, 2014

(54) PHOTOVOLTAIC DEVICE WITH A ZINC OXIDE LAYER AND METHOD OF FORMATION

(71) Applicant: FIRST SOLAR, INC, Perrysburg, OH (US)

(72) Inventors: Benyamin Buller, Sylvania, OH (US); Daniel Damjanovic, Perrysburg, OH (US); Feng Liao, Perrysburg, OH (US); Rick C. Powell, Ann Arbor, MI (US); Jigish Trivedi, Perrysburg, OH (US); Zhibo Zhao, Novi, MI (US)

(73) Assignee: FIRST SOLAR, INC, Perrysburg, OH (US)

(21) Appl. No.: 14/209,206

(22) Filed: Mar. 13, 2014

Related U.S. Application Data
(60) Provisional application No. 61/790,000, filed on Mar. 15, 2013.

(51) Int. Cl. H01L 31/0296; H01L 31/18; H01L 31/0272

(52) U.S. Cl. CPC H01L 31/0296; H01L 31/0272; H01L 31/1828
USPC 136/260; 136/265; 438/85; 438/86

(57) ABSTRACT

Photovoltaic devices with a zinc oxide layer replacing all or part of at least one of a window layer and a buffer layer, and methods of making the devices.

### CROSS-REFERENCE TO RELATED APPLICATION

This application claims priority to U.S. Provisional Application No. 61/790,000, filed on Mar. 15, 2013, which is hereby fully incorporated by reference.

### FIELD OF THE INVENTION

The present invention relates to the field of photovoltaic devices, including photovoltaic cells and photovoltaic modules containing a plurality of photovoltaic cells. More particularly, the invention relates to the use of a zinc oxide layer within a photovoltaic device.

### BACKGROUND OF THE INVENTION

Photovoltaic (PV) devices are PV cells or PV modules containing a plurality of PV cells, or any device that converts photo-radiation or light into electricity. Generally, a thin film PV device includes two conductive electrodes sandwiching a series of semiconductor layers. A buffer layer may be provided on one of the conductive electrodes to provide a smooth surface upon which the semiconductor layers can be formed. The semiconductor layers include an n-type window layer in close proximity to a p-type absorber layer to form a p-n junction. During operation, light passes through the window layer, and is absorbed by the absorber layer. The absorber layer produces photo-generated electron-hole pairs, the movement of which, promoted by an electric field generated at the p-n junction, produces electric current that can be output to other electrical devices through the two electrodes.

Since an electric field, formed by the p-n junction, is required to provide electric current, the window layer should be sufficiently thick to maintain the p-n junction with the nearby absorber layer. Unfortunately, the window layer, e.g. CdS, as well as the underlying buffer layer, if provided, absorb a portion of the light before it reaches the absorber layer, thus reducing the number of photo-generated electron-hole pairs (i.e., carriers) that are available to produce electricity and reducing the short circuit current density (a measure of the maximum current available from a solar cell per unit area). It would be desirable to provide a PV device structure that allows more light to reach the absorber layer. It would also be desirable to reduce the cost of device fabrication.

### BRIEF DESCRIPTION OF THE DRAWINGS

FIGS. 1, 1A and 1B are photovoltaic devices with a zinc oxide layer in accordance with disclosed embodiments;

FIG. 2 is a photovoltaic device with a zinc oxide layer in accordance with a disclosed embodiment;

FIG. 3 is a photovoltaic device with a zinc oxide layer in accordance with a disclosed embodiment; and

FIG. 4 is a photovoltaic device with a zinc oxide layer in accordance with a disclosed embodiment.

### DETAILED DESCRIPTION OF THE INVENTION

Embodiments described herein provide a PV device and a method of forming a PV device which includes a zinc oxide layer provided in a way which increases the amount of photons which reach the absorber layer. The included zinc oxide layer is provided to: (1) eliminate or reduce the thickness of a conventional semiconductor window layer, (2) replace a conventional buffer layer, or (3) both. The reduction of material thickness in the path of incident photons results in enhancement of device performance by allowing more photons to reach the absorber layer. For illustrative purposes, embodiments are described below with reference to a thin film PV device, which may include a PV cell, a collection of cells forming a module, or any portion or combination thereof. However, it should be understood that the embodiments may apply to devices other than thin film devices.

Now referring to the accompanying figures, wherein like reference numbers denote like features, FIG. 1 illustrates an exemplary PV device 100. The device 100 includes a substrate 101. The substrate 101 is used to protect the PV device 100 from environmental hazards. Since the first layer that may be encountered by light incident on the PV device 100 is substrate 101, it should be made of a transparent material such as silicate glass, soda-lime glass, or borosilicate glass or another suitable transparent material Over the transparent substrate 101 is an optional barrier layer 103 used to inhibit sodium, which is present in substrate 101 materials, from diffusing to the other layers of the PV device 100. Sodium diffusion into these layers may adversely affect device efficiency. The optional barrier layer 103 can be a bi-layer of an SnO₂ layer over the substrate 101 and an SiO₂ layer over the SnO₂ layer, a single layer of SiO₂ or SnO₂, or can be formed of, for example, alumina, or silicon aluminum oxide. The barrier layer 103 can have a thickness of between about 1 Å and about 5000 Å, for example between about 50 Å and about 1000 Å. A TCO layer 105 which functions as one of the electrodes of the device 100 is formed over the barrier layer 103. Since light has to pass through the TCO layer 105 to reach the semiconductor layers where it is converted to electricity, it may be made of a transparent conductive material such as indium tin oxide (ITO), fluorine doped tin oxide (SnO₂:F), cadmium stannate (Cd₂SnO₄), indium gallium oxide, or indium titanium oxide. The TCO layer 105 may be formed to a thickness of about 0.2 μm to about 0.5 μm. A buffer layer 107, is formed over the TCO layer 105 for providing a smooth layer for deposition of a zinc oxide layer 108. The buffer layer 107 may be made of a metal oxide such as SnO₂, or a combination of ZnO and SnO₂, and can be about 25 nm to about 200 nm thick. For example, the buffer layer 107 may be between about 50 nm to about 100 nm thick, or about 75 nm thick.

Over the buffer layer 107, a zinc oxide layer 108 is formed adjacent to the buffer layer 107 and in electrical association with the TCO layer 105. As shown, at least a portion of the zinc oxide layer 108 is in contact with a portion of the buffer layer 107. The zinc oxide layer is believed to have n-type semiconductor characteristics and has a thickness between about 1 nm and about 500 nm, for example between about 25 nm and about 200 nm, or between about 40 nm and about 75 nm. Over the zinc oxide layer 108, an n-type semiconductor window layer 109 is formed adjacent to zinc oxide layer 108. As shown, at least a portion of the window layer 109 is in contact with the zinc oxide layer 108. Semiconductor window layer 109 is preferably formed of cadmium sulfide, however it should be understood that other n-type semiconductors may be used including, but not limited to, cadmium zinc sulfide. Window layer 109 thickness may be between about 50 Å and about 2000 Å, between about 50 Å and about 1000 Å, between about 75 Å and about 500 Å, or greater than 0 Å and less than about 200 Å.

Over the window layer 109 a semiconductor absorber layer 111 is formed adjacent to semiconductor window layer 109. As shown, at least a portion of the absorber layer 111 is in contact with the window layer 109. Absorber layer 111 is a p-type semiconductor that may be made of, for example, cadmium telluride, copper indium gallium (di)selenide (CIGS), copper indium selenide, copper gallium selenide, or CdSₓTe₁₋ₓ, which is an alloy of cadmium (Cd), sulfur (S), and tellurium (Te) (where x is greater than zero and less than one and represents the atomic ratio of sulfur to tellurium in the alloy material), as an example, x can be greater than 0 and less than or equal to about 0.3). However it should be understood that other p-type semiconductors may be used. As one alternative, shown in FIG. 1A, the absorber layer 111 may include a bi-layer of CdSₓTe₁₋ₓ 111a and cadmium telluride 111b. In an absorber layer 111 including CdSₓTe₁₋ₓ 111a and cadmium telluride 111b, the CdSₓTe₁₋ₓ material 111a can be closer than the cadmium telluride material 111b to the zinc oxide layer 108. Absorber layer 111 thickness may be between about 0.5 μm and about 10 μm, between about 1 μm and about 5 μm, or between about 2 μm and about 4 μm. If a CdSₓTe₁₋ₓ layer is included in the absorber layer 111, the CdSₓTe₁₋ₓ material 111a portion of the absorber layer 111 thickness can be between about 20 nm to about 500 nm.

After the absorber layer 111 is deposited, the PV device 100 may be treated with a compound comprising chlorine, such as CdCl₂, and heated to reduce the resistivity of the semiconductor materials through re-crystallization and incorporation of chlorine within the semiconductor materials, particularly the absorber layer. The PV device 100 may be heated to greater than about 400° C., for example, the PV device 100 may be heated to about 440° C., or heated to a first temperature in a first heating at about 440° C., and then heated to a second temperature in a second heating at about 430° C. It should be understood that the chlorine application and heat treatment will vary with the type and thickness of the absorber layer 111 as well as the combination of other PV device layers.

A back contact layer 113 can be formed adjacent and in electrical association with the absorber layer 111 to form an electrode for conveying electricity out of the PV device 100. The back contact layer 113 can be formed from a metal, for example, molybdenum, aluminum, copper, gold, alloys thereof, or mixtures of any of the foregoing. A back cover 115 can be formed to provide environmental protection or support for the structure and may be made, for example, as the same materials used to make the substrate 101 or other materials. Optionally, additional materials or layers may be included in the PV device 100. For example, as shown in FIG. 1B, a zinc telluride layer 112 may be formed between the absorber layer 111 and the back contact metal layer 113, which has been experimentally shown to improve device efficiency by reducing electron/hole re-combination losses at the absorber layer 111/back contact layer 113 interface. The zinc telluride layer 112, if employed, can have a thickness of about 10 nm to about 500 nm. The zinc telluride layer 112 can also be employed in the FIG. 1A structure between the absorber layer 111 and back contact layer 113.

The layers of PV device 100, may be formed using any suitable technique or combination of techniques. For example, the layers can be formed by chemical vapor deposition (CVD), physical vapor deposition (PVD), chemical bath deposition (CBD), low pressure chemical vapor deposition, atmospheric pressure chemical vapor deposition, plasma-enhanced chemical vapor deposition, thermal chemical vapor deposition, DC or AC sputtering, spin-on deposition, spray-pyrolysis, vapor transport deposition (VTD), close space sublimation (CSS) etc. or a combination thereof. These processes are well known in the industry and thus will not herein be explained.

PV device 100, illustrated in FIGS. 1, 1A and 1B, has improved open circuit voltage (V_{oc}) (a measure of the maximum voltage available from a solar cell) and short circuit current density as compared to a PV device having the same layer combination as FIG. 1 but without a zinc oxide layer 108. It is believed that the zinc oxide layer 108, having n-type characteristics, also functions as a window layer, and contributes, along with window layer 109, to maintaining a sufficient p-n junction with the absorber layer 111. Thus, by adding a zinc oxide layer 108, the cadmium sulfide window layer 109 itself can be made thinner than in a PV device without zinc oxide layer 108. For example, in a PV device without zinc oxide layer 108, window layer 109 thickness may need to be greater than 400 Å to provide a sufficient p-n junction between the window layer 109 and the absorber layer 111. Zinc oxide also has less optical absorption than cadmium sulfide, thus there is in an overall increase in light passing through the combination of a zinc oxide layer 108 and a thinner (≦400 Å) window layer 109 for photo-conversion within absorber layer 111. Therefore, photo-conversion efficiency is increased as compared to a PV device with a thicker (>400 Å) cadmium sulfide window layer.

FIG. 2 illustrates an exemplary embodiment of a PV device 200 similar to PV device 100 including a zinc oxide layer 208 and a window layer 209, among other layers of PV device 100 described with reference to FIG. 1. The layers may be formed using similar techniques, formed to similar thicknesses, and formed of similar materials as those described above with reference to PV device 100. However, PV device 200 omits buffer layer 107 (FIG. 1). As shown, at least a portion of zinc oxide layer 208 is in contact with TCO layer 105. PV device 200 has improved open circuit voltage and short circuit current density as compared to a PV device having the same layer combination as FIG. 1 but without the zinc oxide layer 108. It is believed that the zinc oxide layer 208 serves as a buffer layer by providing a sufficiently smooth surface for the deposition of the window layer 209. Furthermore, the zinc precursors used to form zinc oxide costs less than those materials commonly used for buffer layer 107, such as tin oxide. Therefore, by including zinc oxide layer 208 and omitting a buffer layer 107, the cost of materials can decrease.

FIG. 3 illustrates an exemplary embodiment of a PV device 300 similar to PV device 100 including a buffer layer 307 and a zinc oxide layer 308, among other layers of PV device 100 described with reference to FIG. 1. The layers may be formed using similar techniques, formed to similar thicknesses, and formed of similar materials as those described above with reference to PV device 100. However, PV device 300 omits window layer 109 (FIG. 1). As shown, at least a portion of absorber layer 111 is in contact with zinc oxide layer 308. PV device 300 has improved open circuit voltage and short circuit current density as compared to a PV device having the same layer combination as FIG. 1 but without the zinc oxide layer 108. It is believed that the n-type characteristics of zinc oxide layer 308 serves as a window layer by providing a p-n junction with absorber layer 111. As noted above, zinc oxide layer 308 has increased transparency over other materials commonly used for window layers, such as cadmium sulfide. As such, the use of a zinc oxide layer 308 as the window layer can allow more photons to reach the semiconductor absorber layer 111 and thus increase photo-conversion efficiency as compared to a more conventional PV device with a cadmium sulfide window layer. Furthermore, zinc precursors used to form zinc oxide costs less than cadmium sulfide. Therefore, by including zinc oxide layer 308 and omitting a cadmium sulfide window layer 109 (FIG. 1), the cost of materials can decrease.

FIG. 4 illustrates an exemplary embodiment of a PV device 400 similar to PV device 100 including a zinc oxide layer 408 among other layers of PV device 100 described with reference to FIG. 1. The layers may be formed using similar techniques, formed to similar thicknesses, and formed of similar materials as those described above with reference to PV device 100. However, PV device 400 omits buffer layer 107 (FIG. 1) and window layer 109 (FIG. 1). As shown, at least a portion of absorber layer 111 is in contact with zinc oxide layer 408 and at least a portion of zinc oxide layer 408 is in contact with TCO layer 105. PV device 400 has improved open circuit voltage and short circuit current density as compared to a PV device having the same layer combination as FIG. 1 but without the zinc oxide layer 108. Here, it is believed that the n-type characteristics of zinc oxide layer 308 allows it to serve as a window layer by providing the p-n junction with absorber layer 111 while it also serves as a buffer layer by providing a sufficiently smooth surface for the deposition of the semiconductor absorber layer 111. As noted above, zinc oxide has increased transparency over other materials commonly used for window layers, such as cadmium sulfide, such that the use of a zinc oxide layer 408 as a window layer can allow more photons to reach the semiconductor absorber layer 111 and thus increase photo-conversion efficiency (due to increased current density) as compared to a PV device with a cadmium sulfide window layer. Furthermore, the zinc precursors used to form zinc oxide costs less than cadmium sulfide and materials commonly used as buffer materials, such as tin oxide. Therefore, by including zinc oxide layer 308 and omitting a cadmium sulfide window layer 109 (FIG. 1) and buffer layer 107 (FIG. 1), the cost of materials can decrease.

Each of the embodiments in FIGS. 2-4 can also include the absorber bi-layer 111a, 111b described above with reference to FIG. 1A and/or the ZnTe layer 112 discussed above with reference to FIG. 1B

The embodiments described above are offered by way of illustration and example. Each layer in PV devices 100, 200, 300, 400 may, in turn, include more than one layer or film. Additionally, each layer can cover all or a portion of the PV device 100, 200, 300, 400 and/or all or a portion of the layer or substrate underlying the layer. For example, a “layer” can include any amount of any material that contacts all or a portion of a surface. It should be understood that the examples provided above may be altered in certain respects and still remain within the scope of the claims. It should be appreciated that, while the invention has been described with reference to the above preferred embodiments, other embodiments are within the scope of the claims. The invention should also not be considered as limited to those embodiments, but is only limited by the scope of the claims appended hereto.

What is claimed as new and desired to be protected by Letters Patent of the United States is:

1. A photovoltaic device comprising:
a first and a second electrode;
a zinc oxide layer providing the function of at least one of a buffer layer and a window layer, the zinc oxide layer being in electrical association with the first electrode; and
a semiconductor absorber layer in electrical association with the second electrode.

2. A photovoltaic device of claim 1, wherein the zinc oxide layer functions as a window layer and is in contact with the semiconductor absorber layer.

3. A photovoltaic device of claim 2, wherein the first electrode comprises a transparent conductive oxide layer in contact with a surface of the zinc oxide layer facing away from the absorber layer.

4. The photovoltaic device of claim 3, wherein the zinc oxide layer has a thickness between about 1 nm to about 500 nm.

5. The photovoltaic device of claim 3, wherein the semiconductor absorber layer comprises cadmium telluride.

6. The photovoltaic device of claim 5, wherein the semiconductor absorber layer comprises a bi-layer of CdTe material and CdSₓTe₁₋ₓ material where x is greater than 0 and less than or equal to about 0.3 and the zinc oxide layer is closer to the CdSₓTe₁₋ₓ material than to the CdTe material.

7. The photovoltaic device of claim 5, further comprising a zinc telluride layer between the semiconductor absorber layer and the second electrode.

8. The photovoltaic device of claim 1, further comprising a buffer layer, wherein the first electrode comprises a transparent conductive oxide layer and the buffer layer is in contact with the transparent conductive oxide layer and the zinc oxide layer, the transparent conductive oxide layer contacting a surface of the buffer layer facing away from the zinc oxide layer.

9. The photovoltaic device of claim 8, wherein the semiconductor absorber layer is in contact with a surface of the zinc oxide layer facing away from the buffer layer.

10. The photovoltaic device of claim 9, wherein the semiconductor absorber layer comprises cadmium telluride.

11. The photovoltaic device of claim 10, wherein the semiconductor absorber layer comprises a bi-layer of CdTe material and CdSₓTe₁₋ₓ material where x is greater than 0 and less than or equal to about 0.3 and the zinc oxide layer is closer to the CdSₓTe₁₋ₓ material than to the CdTe material.

12. The photovoltaic device of claim 10, further comprising a zinc telluride layer between the semiconductor absorber layer and the second electrode.

13. The photovoltaic device of claim 11, wherein the zinc oxide layer has a thickness between about 1 nm to about 500 nm.

14. The photovoltaic device of claim 9, wherein the buffer layer has a thickness between about 25 nm to about 200 nm.

15. The photovoltaic device of claim 8, further comprising a semiconductor window layer, wherein the semiconductor window layer is between the zinc oxide layer and the semiconductor absorber layer.

16. The photovoltaic device of claim 15, wherein the semiconductor window layer is in contact with a surface of the zinc oxide layer facing away from the buffer layer.

17. The photovoltaic device of claim 16, wherein the absorber layer is in contact with a surface of the window layer facing away from the zinc oxide layer.

18. The photovoltaic device of claim 17, wherein the semiconductor window layer comprises cadmium sulfide.

19. The photovoltaic device of claim 18, wherein the semiconductor absorber layer comprises cadmium telluride.

20. The photovoltaic device of claim 19, wherein the semiconductor absorber layer comprises a bi-layer of CdTe material and CdSₓTe₁₋ₓ material where x is greater than 0 and less than or equal to about 0.3 and the zinc oxide layer is closer to the CdSₓTe₁₋ₓ material than to the CdTe material.

21. The photovoltaic device of claim 19, further comprising a zinc telluride layer between the semiconductor absorber layer and the second electrode.

22. The photovoltaic device of claim 19, wherein the buffer layer comprises tin oxide.

23. The photovoltaic device of claim 17, wherein the semiconductor window layer has a thickness greater than 0 nm and less than about 200 nm.

24. The photovoltaic device of claim 17, wherein the zinc oxide layer has a thickness between about 1 nm and about 500 nm.

25. The photovoltaic device of claim 17, wherein the buffer layer has a thickness between about 25 nm and about 200 nm.

26. The photovoltaic device of claim 1, further comprising a semiconductor window layer, wherein the semiconductor window layer is between the absorber layer and the zinc oxide layer.

27. The photovoltaic device of claim 20, wherein the window layer is in contact with the absorber layer and the zinc oxide layer, the zinc oxide layer contacting a surface of the window layer facing away from the absorber layer.

28. The photovoltaic device of claim 21, wherein the first electrode comprises a transparent conductive oxide layer in contact with a surface of the zinc oxide layer facing away from the window layer.

29. The photovoltaic device of claim 22, wherein the semiconductor absorber layer comprises cadmium telluride.

30. The photovoltaic device of claim 29, wherein the semiconductor absorber layer comprises a bi-layer of CdTe material and CdSₓTe₁₋ₓ material where x is greater than 0 and less than or equal to about 0.3 and the zinc oxide layer is closer to the CdSₓTe₁₋ₓ material than to the CdTe material.

31. The photovoltaic device of claim 29, further comprising a zinc telluride layer between the semiconductor absorber layer and the second electrode.

32. The photovoltaic device of claim 29, wherein the semiconductor window layer comprises cadmium sulfide.

33. The photovoltaic device of claim 30, wherein the zinc oxide layer has a thickness between about 1 nm to about 500 nm.

34. The photovoltaic device of claim 30, wherein the semiconductor window layer has a thickness greater than 0 nm and less than about 200 nm.

35. A method of forming a photovoltaic device, comprising:
forming a first electrode,
forming a zinc oxide layer providing the function of at least one of a buffer layer and a window layer, the zinc oxide layer being formed in electrical association with the first electrode; and
forming a semiconductor absorber layer.
forming a second electrode in electrical association with the semiconductor absorber layer.

36. The method of claim 35, wherein the semiconductor absorber material is formed to contact the zinc oxide layer, the zinc oxide layer formed to function as a window layer.

37. The method of claim 36, wherein the first electrode comprises a transparent conductive oxide layer, where the transparent conductive oxide layer is formed to contact the zinc oxide layer on a surface facing away from the absorber layer.

38. The method of claim 37, wherein the zinc oxide layer is formed to a thickness between about 1 nm to about 500 nm.

39. The method of claim 37, wherein the semiconductor absorber layer comprises cadmium telluride.

40. The method of claim 39, wherein the semiconductor absorber layer comprises a bi-layer of CdTe and CdSₓTe₁₋ₓ where x is greater than 0 and less than or equal to about 0.3 and the zinc oxide layer is closer to the CdSₓTe₁₋ₓ material than to the CdTe material.

41. The method of claim 39, further comprising forming a zinc telluride layer between the semiconductor absorber layer and the second electrode.

42. The method of claim 35, further comprising forming a buffer layer, wherein the first electrode comprises a transparent conductive oxide layer and the buffer layer is formed in contact with the transparent conductive oxide layer and the zinc oxide layer, the transparent conductive oxide layer formed to contact a surface of the buffer layer facing away from the zinc oxide layer.

43. The method of claim 42, wherein the semiconductor absorber layer is formed in contact with a surface of the zinc oxide layer facing away from the buffer layer.

44. The method of claim 43, wherein the semiconductor absorber layer comprises cadmium telluride.

45. The method of claim 44, wherein the semiconductor absorber layer comprises a bi-layer of CdTe and CdSₓTe₁₋ₓ where x is greater than 0 and less than or equal to about 0.3 and the zinc oxide layer is closer to the CdSₓTe₁₋ₓ material than to the CdTe material.

46. The method of claim 44, further comprising forming a zinc telluride layer between the semiconductor absorber layer and the second electrode.

47. The method of claim 43, wherein the zinc oxide layer has a thickness between about 1 nm to about 500 nm.

48. The method of claim 43, wherein the buffer layer has a thickness between about 25 nm to about 200 nm.

49. The method of claim 42, further comprising forming a semiconductor window layer, wherein the semiconductor window layer is formed between the zinc oxide layer and the semiconductor absorber layer.

50. The method of claim 49, wherein the semiconductor window layer is in contact with a surface of the zinc oxide layer facing away from the buffer layer.

51. The method of claim 50, wherein the absorber layer is in contact with a surface of the window layer facing away from the zinc oxide layer.

52. The method of claim 51, wherein the semiconductor window layer comprises cadmium sulfide.

53. The method of claim 52, wherein the semiconductor absorber layer comprises cadmium telluride.

54. The method of claim 53, wherein the semiconductor absorber layer comprises a bi-layer of CdTe and CdSₓTe₁₋ₓ where x is greater than 0 and less than or equal to about 0.3 and the zinc oxide layer is closer to the CdSₓTe₁₋ₓ material than to the CdTe material.

55. The method of claim 53, further comprising forming a zinc telluride layer between the semiconductor absorber layer and the second electrode.

56. The method of claim 53, wherein the buffer layer comprises tin oxide.

57. The method of claim 51, wherein the semiconductor window layer is has a thickness greater than 0 nm and less than about 200 nm.

58. The method of claim 51, wherein the zinc oxide layer has a thickness between about 1 nm and about 500 nm.

59. The method of claim 51, wherein the buffer layer has a thickness between about 25 nm and about 200 nm.

60. The method of claim 35, further comprising forming a semiconductor window layer, wherein the semiconductor window layer is between the absorber layer and the zinc oxide layer.

61. The method of claim 60, wherein the window layer is in contact with the absorber layer and the zinc oxide layer, the zinc oxide layer contacting a surface of the window layer facing away from the absorber layer.

62. The method of claim 61, wherein the first electrode comprises a transparent conductive oxide layer in contact with a surface of the zinc oxide layer facing away from the window layer.

63. The method of claim 62, wherein the semiconductor absorber layer comprises cadmium telluride.

64. The method of claim 63, wherein the semiconductor absorber layer comprises a bi-layer of CdTe and CdSₓTe₁₋ₓ where x is greater than 0 and less than or equal to about 0.3 and the zinc oxide layer is closer to the CdSₓTe₁₋ₓ material than to the CdTe material.

65. The method of claim 63, further comprising forming a zinc telluride layer between the semiconductor absorber layer and the second electrode.

66. The method of claim 63, wherein the semiconductor window layer comprises cadmium sulfide.

67. The method of claim 66, wherein the zinc oxide layer has a thickness between about 1 nm to about 500 nm.

68. The method of claim 66, wherein the semiconductor window layer has a thickness greater than 0 nm and about less than about 200 nm.
